(19) United States
(12) Patent Application Publication
(10) Pub. No.: US 2022/0283242 A1
(43) Pub. Date: Sep. 8, 2022

(54) METHOD AND DEVICE FOR MANAGING BATTERY DATA

(71) Applicant: GOTION, INC., Fremont, CA (US)

(72) Inventors: Xiaojun LI, Fremont, CA (US); Jianwei LI, Fremont, CA (US)

(21) Appl. No.: 17/684,985

(22) Filed: Mar. 2, 2022

(30) Foreign Application Priority Data
Mar. 3, 2021 (CN) 202110233008.2

(51) Int. Cl. G01R 31/396; G01R 31/382; G01R 31/367; G08B 21/18; B60L 58/12; B60L 3/00; B60Q 9/00

(52) U.S. Cl. CPC G01R 31/396; G01R 31/382; G01R 31/367; G08B 21/185; B60L 58/12; B60L 3/0046; B60Q 9/00; B60L 2240/545; B60L 2240/547; B60L 2240/549; B60L 2240/12; B60L 2240/62

(57) ABSTRACT

The embodiments of this disclosure provide a method and a device for managing battery data. The method comprises: acquiring cell data and battery data, which describe statuses of a cell and a battery pack, respectively; calculating an estimated battery status, which indicates a status of the cell and the battery pack after an estimation time period, based on the cell data and the battery data; sending an alarm message to a user if the estimated battery status meets a battery failure condition. With the method described above, the current battery data is effectively utilized to estimate the subsequent battery status to predict potential battery failure in advance, rather than recognize the failure from the detected battery data when the battery has failed. In this way, it is possible to avoid battery failures effectively, prevent the battery failures from impacting the quality of the battery, and improve the user experience of the battery.

### CROSS-REFERENCE TO RELATED APPLICATIONS

This application claims the priority of Chinese Patent Application No. 202110233008.2, filed on Mar. 3, 2021, entitled “Battery data management method and device”, the entire contents of which are incorporated herein by reference.

### TECHNICAL FIELD

The embodiments of this disclosure relate to the technical field of battery data management, and in particular, to a method and device for managing battery data.

### BACKGROUND

With the rapid development of electric vehicles and energy storage systems, energy storage batteries have also been subjected to extensive development and application. The use of batteries brings about a large amount of data such as cell voltage, cell temperature, battery pack voltage, battery pack temperature. Therefore, a battery management system is usually provided in the battery pack to collect battery data and manage the batteries based on the battery data.

However, the conventional battery management systems are basically capable of only acquiring current status of a battery from battery data. To estimate the battery failure, it is necessary to set an alarm zone in advance so that an alarm is triggered when the current status of the battery enters into the alarm zone. However, such an arrangement cannot accurately predict the battery status. Therefore, it is insufficient in accuracy and inadequate in terms of battery management. It remains a need for a method for managing batteries capable of predicting the battery failure status accurately.

### SUMMARY

An objective of the embodiments in this disclosure is to provide a method and device for managing battery data, which achieve an accurate estimation of the battery status.

An embodiment of this disclosure provides a method for managing battery data, comprising: acquiring cell data and battery data, which describe statuses of a cell and a battery pack, respectively; calculating an estimated battery status which indicates a status of the cell and the battery pack after an estimation time period, based on the cell data and the battery data; sending an alarm message to a user if the estimated battery status meets a battery failure condition.

An embodiment of this disclosure further provides a device for managing battery data, comprising: a data acquiring module configured to acquire cell data and battery data, which describe statuses of a cell and a battery pack, respectively; a battery status estimating module configured to calculate an estimated battery status, which indicates statuses of the cell and the battery pack after an estimation time period, based on the cell data and the battery data; an alarm message sending module configured to send an alarm message to a user if the estimated battery status meets a battery failure condition.

According to the embodiments of this disclosure, upon acquisition of the data of the cell and the battery pack, the status of the cell and the battery pack after the estimation time period is estimated based on the cell data and the battery data. An alarm message will be sent to the user if the estimated battery status meets the battery failure condition. In other words, there is a strong possibility of battery failure in view of the current status. According to the embodiments, the current battery data is effectively utilized to estimate the subsequent battery status to predict potential failure of the battery in advance, rather than recognize the failure from the detected battery data when the battery was faulted. In this way, it is possible to effectively avoid battery failures, prevent the battery failures from impacting the battery's quality, and improve its user experience.

### BRIEF DESCRIPTION OF DRAWINGS

To explain the technical solutions of the embodiments in this disclosure or the prior art more clearly, a brief introduction will be made to the drawings for the embodiments or the prior art. It is to be understood that the drawings described below involve only some embodiments described in this disclosure, and those skilled in the art may arrive at drawings for other embodiments from this disclosure without creative efforts.

FIG. 1 is a flow chart of a method for managing battery data according to an embodiment of this disclosure;

FIG. 2 is a module diagram of a device for managing battery data according to an embodiment of this disclosure.

### DESCRIPTION OF EMBODIMENTS

A clear and complete description will be made to the technical solutions of the embodiments in this disclosure in conjunction with the drawings. It can be understood that the described embodiments are only a part, rather than all, of the embodiments of this invention and that all other embodiments obtained by those skilled in the art from this disclosure without creative efforts shall fall within the scope of this disclosure.

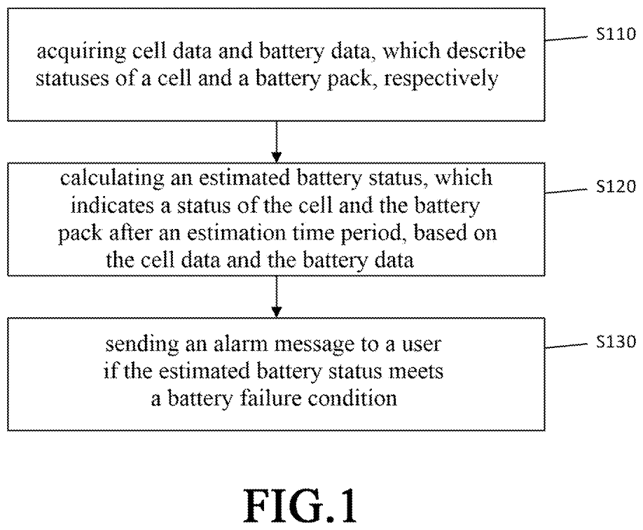

To solve the above technical problems, the embodiments of this disclosure provide a method for managing battery data. As shown in FIG. 1, the method for managing battery data comprises the following steps.

S110: acquiring cell data and battery data, which describe statuses of a cell and a battery pack, respectively.

The cell is the smallest unit in the power battery for storing electric energy and generally has a high energy density. When electric energy is needed, the stored electric energy is discharged to achieve a power supply. However, the cell may malfunction due to factors such as voltage, current, or temperature, and the failure of a single cell may result in the failure of the entire battery. Therefore, it is of great significance to recognize and prevent battery failures promptly.

To grasp the cell's status, it is generally necessary to acquire the cell data generated by the cell. Specifically, the cell data may include at least one cell temperature, cell voltage, and cell charging/discharging current. Based on the cell data and predetermined standards, the current specific status of the cell can be determined, for example, whether it is in a failure status or a normal status. However, when it is recognized that the cell is in a failure status from the cell data, the regular use of the battery has been impaired to some extent. Therefore, it is desired to estimate an upcoming status based on the battery data.

The battery data may be data describing the status of the battery pack, for example, at least one of battery-pack voltage, battery-pack temperature, and battery-pack charging/discharging current. A battery pack is generally a component obtained by assembling a module composed of multiple cells and an associated battery management module. The battery pack can independently manage the included cells and other units.

Associated sensing devices may collect the battery data and cell data. For example, the temperature may be measured by a temperature sensor, and the current may be measured by a galvanometer. In practical applications, there is no limitation on the way of acquiring battery data and cell data, and details are omitted herein.

In practical applications, the cell data and the battery data may be stored in various formats. For example, it may be recorded in Excel, CSV/TXT, Measurement Data Format (MDF), and Controller Area Network (CAN). Accordingly, an associated device may read and analyze the data in a relevant format. The specific process may be configured according to the requirements of practical applications, and details are omitted herein. The cell data and the battery data may also be real-time data sent by an onboard BMS wireless terminal to ensure the timeliness of the data and adapt to data processing in different scenarios.

In some embodiments, the acquired cell data and battery data may be time-series sample data. The data may be stored according to the various characteristics of the data respectively. For example, a part of the time-series sample data, such as cell/module/battery pack voltage, temperature, charging/discharging current, vehicle speed, etc., may be stored in a non-relational database. Accordingly, annotation information for the time-series data, including locations where the data are acquired, associations between data, and so on, may be stored in a relational database.

In the subsequent steps, the status estimating model and associated sample data may be stored in the relational database for training and utilizing the model.

In some embodiments, the managed battery may be onboard, i.e., a battery for driving an electric vehicle. Accordingly, vehicle data associated with a vehicle in which the battery resides may also be acquired while acquiring the cell and battery data. Specifically, the vehicle data may include at least one of vehicle speed and vehicle location. Accordingly, in the subsequent steps, further analysis may be performed in conjunction with the vehicle status when estimating the battery status to improve the accuracy of the estimated battery status by taking into account the usage conditions of the battery.

In some embodiments, to ensure the quality of the acquired cell data and battery data, the cell data and/or battery data may be subjected to a preprocessor. The preprocessor may include at least one of the functions: removing invalid data, denoising, complementing missing data, and transcoding. The preprocessing may improve the quality of the cell data and the battery data effectively to be effectively utilized in the subsequent analysis process.

S120: calculating an estimated battery status, which indicates a status of the cell and the battery pack after an estimation time period, based on the cell data and the battery data.

After the cell data and the battery data are acquired, an estimated battery status, which indicates a status of the cell and the battery pack after an estimation time period, may be calculated based on the cell data and the battery data, that is, the subsequent change of the battery status is estimated based on the current status of the battery. The estimation time period may be set depending on the requirements of practical applications. For example, it may be 30 seconds, one minute, five minutes, etc. In practice, the estimation time period may be determined comprehensively depending on the requirements in terms of the time span of the estimation and precision of the estimation. Details are omitted herein.

In some embodiments, the estimated battery status may be calculated with a status estimating model. The status estimating model may be a neural network model for estimating the battery's state of charge and may include dimensions of input and output, the number of hidden layers, the respective weights, and the associated time-series data for training and verifying the model. The neural network model may be pre-built by an engineer and then trained based on battery data and cell data labeled with the battery status. The neural network model may be utilized to simulate subsequent battery developments based on the current status of the battery. The specific design of the model may be configured and adjusted following the requirements of practical applications. There is no limitation in this respect.

In some embodiments, a battery-system simulation environment may be constructed first to obtain the status estimating model. The battery-system simulation environment may include a standard numerical solver, such as the Runge-Kutta method, and/or a typical battery physical model, such as Resistor-capacitor (RC) circuit model. In practical applications, other numerical solvers may be adopted according to practical requirements. After that, the sample battery data is acquired. The sample battery data may be labeled with the battery failure status. In other words, a supervised learning is to be performed with the labeled data to train the model. Finally, the pre-built status estimating model is trained based on the sample battery data. The status estimating model may be a long-short memory loop neural network model (LSTM), etc. With the built battery-system simulation environment, the status estimating model enables the estimation of the state of charge (SOC) and the state of health (SOH) of the battery and diagnosis and early warning of battery failures.

In some embodiments, to ensure that the involved computational capability matches the acquired data, the acquired battery data and cell data may be sent to a data processing device for processing.

The data processing device may be a device that stores data and analyzes and processes the data. For example, the data processing device may perform calculations based on big data and provide related cloud services. In other words, the data processing device may be a cloud computing device. Preferably, the communication between the data processing device and the battery management device is wireless, ensuring the stability of the communication between these two devices.

Accordingly, a corresponding data transmission module may be provided in the battery management device to communicate with the data processing device. The data transmission module may preferably transmit wireless signals to the data processing device to communicate with the data processing device. Accordingly, the data transmission module may be configured to receive wireless signals sent from the data processing device. In practical applications, the data transmission module may also perform data transmission in a wired manner. There is no limitation in this respect.

In some embodiments, the data transmission module may be further configured to receive update parameters and update codes. The update parameters and update codes are for updating the program code of the battery management device so that the version upgrading of the battery management device can be implemented conveniently and quickly, and the processing capability of the device can be improved.

The above-mentioned neural network model may be stored in the data processing device for obtaining corresponding calculation results for the data. Accordingly, the data processing device may acquire sample data corresponding to other battery management scenarios based on big data to train or optimize the model with the acquired sample data to improve management.

S130: sending an alarm message to a user if the estimated battery status meets a battery failure condition.

After the estimated battery status is acquired, it may be compared with the battery failure condition. The battery failure condition may be a particular value for determining whether the battery has failed.

In some embodiments, the battery failure condition may be at least one of an over-voltage failure condition, an under-voltage failure condition, an over-temperature failure condition, an over-current failure condition, a low charge condition, and a low power condition. The over-voltage failure condition may involve a voltage value for tackling the over-voltage of the battery. The under-voltage failure condition may involve a voltage value for tackling the under-voltage of the battery. The over-temperature failure condition may involve a temperature value for tackling the over-temperature of the battery. The over-current failure condition may involve a current value for tackling the over-current of the battery. The low charge condition may involve a charge value for tackling the low charge of the battery. The low-power condition may involve a power value for tackling the low-power of the battery.

If a certain value of the estimated battery status meets any battery failure conditions, it may be determined that a failure may occur to the battery after a certain period of time. Therefore, it is necessary to warn the user by sending an alarm message to the user.

The alarm message is for informing the user that the current status of the battery is poor and failures may occur and for urging the user to stop using the battery and check the battery status. The user may be a user of the battery. For example, when the battery is onboard, the user may be the driver of the associated vehicle. The user may also be a person who manages the battery data, for example, an operator of the data center that collectively manages the battery data. The destination to which the alarm message is sent may depend on the practical applications, and there is no limitation in this respect.

In some embodiments, the step of sending the alarm message to the user may be sending a report corresponding to the estimated battery status to the user via email. The report may indicate that the battery has a high probability of failure as a warning to the user. Sending the alarm message to the user may also be displaying the data corresponding to the estimated battery status to the user via a visual interface, for example, displaying the corresponding data on a display screen of the vehicle, to enable the driver to know the current status of the battery. In practical applications, the alarm message may be delivered to the user in other manners. There is no limitation in this respect, and further details are omitted herein.

Upon receiving the alarm message, the user may troubleshoot the battery failures based on the alarm message. For example, in the case of low-charge, the user may charge the battery straight away. In the case of over-temperature, the user may stop using the battery to prevent the battery temperature from further rising. For some relatively simple failures, the associated battery management device may handle them autonomously following preset rules. The handling of the failures may depend on specific application conditions, there is no limitation in this respect, and further details are omitted herein.

In some embodiments, if the estimated battery status is calculated by the data processing device, the alarm message may be sent by the data processing device to the user to warn the user. Because the communication capability of the data processing device is generally better than that of the management system attached to the battery, the user may receive the alarm message more quickly, and therefore may cope with the problems in the battery in a more timely manner.

According to the above embodiments, upon acquisition of the data of the cell and the battery pack, the status of the cell and the battery pack after the estimation time period is estimated based on the cell data and the battery data. An alarm message will be sent to the user if the estimated battery status meets the battery failure condition. In other words, there is a strong possibility of battery failure in view of the current status. According to the embodiments, the current battery data is effectively utilized to estimate the subsequent battery status to predict potential battery failure in advance, rather than recognize the failure from the detected battery data when the battery has failed. In this way, it is possible to avoid battery failures effectively, prevent the battery failures from impacting the quality of the battery, and improve the user experience of the battery.

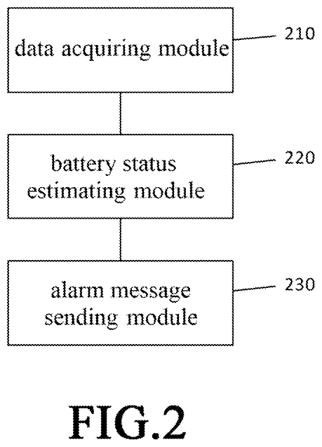

Based on the method for managing battery data described above, an embodiment of this disclosure further provides a device for managing battery data. As shown in FIG. 2, the device for managing battery data comprises the following modules:

a data acquiring module 210 configured to acquire cell data and battery data, which describe statuses of the cell and the battery pack, respectively;

a battery status estimating module 220 configured to calculate an estimated battery status, which indicates a status of the cell and the battery pack after an estimation time period, based on the cell data and the battery data;

an alarm message sending module 230 is configured to send an alarm message to a user if the estimated battery status meets a battery failure condition.

Based on the method for managing battery data described above, an embodiment of this disclosure further provides a device for managing battery data, including a memory and a processor.

In this embodiment, the memory may be implemented in any suitable manner. For example, the memory may be a read-only memory, a mechanical hard disk, a solid-state hard disk, or a flash disk. The memory may store computer program instructions.

In this embodiment, the processor may be implemented in any suitable manner. For example, the processor may take the form of a microprocessor or a processor, as well as a computer-readable medium storing computer-readable program code (such as software or firmware) that may be executed by the (micro) processor, logic gates, switches, Application Specific Integrated Circuits (ASIC), programmable logic controller and embedded microcontroller, etc. The processor may execute the computer program instructions to implement the following steps: acquiring cell data and battery data, which describe statuses of the cell and the battery pack, respectively; calculating an estimated battery status, which indicates a status of the cell and the battery pack after an estimation time period, based on the cell data and the battery data; and sending an alarm message to a user if the estimated battery status meets a battery failure condition.

Although the processes described above include a plurality of operations performed in a specific order, it should be understood that these processes may include more or fewer operations. These operations may be performed sequentially or in parallel (for example, with a parallel processor or a multi-threaded environment).

A description has been made by reference to flowcharts and/or block diagrams of methods, devices (systems), and computer program products according to the embodiments of this disclosure. It should be understood that each process and/or block in the flowcharts and/or block diagrams and the combination of processes and/or blocks in the flowcharts and/or block diagrams can be implemented by computer program instructions. These computer program instructions can be provided to the processor of a general-purpose computer, a special-purpose computer, an embedded processor, or other programmable data processing device to form a machine so that the instructions executed by the processor of the computer or other programmable data processing device achieve a device for implementing the functions specified in one or more processes in the flowcharts and/or one or more blocks in the block diagrams.

These computer program instructions may also be stored in a computer-readable memory that can direct a computer or other programmable data processing device to operate in a specific manner, so that the instructions stored in the computer-readable memory achieve an article of manufacture including the instruction device, with the instruction device implementing the functions specified in one or more processes in the flowcharts and/or one or more blocks in the block diagrams.

These computer program instructions may also be loaded onto a computer or other programmable data processing device to enable the computer or other programmable device to perform a series of operations. In this way, the instructions executed on the computer or other programmable device may provide steps for implementing functions specified in one or more flows in the flowcharts and/or one or more blocks in the block diagrams.

In a typical configuration, the computing device may include one or more processors (CPUs), input/output interfaces, network interfaces, and memory.

The memory may include non-permanent memory, random access memory (RAM), and/or non-volatile memory in a computer-readable medium, such as read-only memory (ROM) or flash memory (flash RAM). Memory is an example of a computer-readable medium.

The computer-readable medium may include permanent and non-permanent, removable and non-removable medium, and may store information by any methods or technology. The information may be computer-readable instructions, data structures, program modules, or other data. Examples of the computer storage medium may include, but are not limited to, phase-change memory (PRAM), static random access memory (SRAM), dynamic random access memory (DRAM), other types of random access memory (RAM), read-only memory (ROM), electrically erasable programmable read-only memory (EEPROM), flash memory or other memory technology, CD-ROM, digital versatile disc (DVD) or other optical storage, magnetic cassettes, disk storage or other magnetic storage devices or any other non-transmission media for storing information accessible to computing devices. According to the definition in this disclosure, computer-readable media does not include transitory medium, such as modulated data signals and carrier waves.

Those skilled in the art should understand that the embodiments of this disclosure can be provided as a method, a system, or a computer program product. Therefore, the embodiments of this disclosure may take the form of an entire hardware embodiment, an entire software embodiment, or an embodiment combining both software and hardware. Moreover, the embodiments of this disclosure may take the form of computer program products implemented on one or more computer-usable storage mediums (including but not limited to disk storage, CD-ROM, optical storage, etc.) containing computer-usable program codes.

The embodiments of this disclosure may be described in the general context of computer-executable instructions executed by a computer, such as program modules. Generally, program modules may include routines, programs, objects, components, data structures, etc., for performing specific tasks or implementing specific abstract data types. The embodiments of this disclosure may also be implemented in a distributed computing environment in which tasks are performed by remote processing devices connected through a communication network. Program modules in the distributed computing environment may be located in local and remote computer storage media, including storage devices.

The embodiments in this disclosure have been described progressively in that each embodiment is described by focusing on the differences from other embodiments, and reference may be made to the same or similar parts across the embodiments. In particular, descriptions of the system embodiments are relatively brief as they are similar to the method embodiments, and reference may be made to the method embodiments for relevant parts. In the description of this disclosure, terms “an embodiment”, “some embodiments”, “an example”, “a specific example”, or “some examples” etc. mean the specific feature, structure, material, or characteristic described in conjunction with the embodiment or example are included in at least one embodiment or example of this disclosure. In this disclosure, reference to these terms is not necessarily limited to the same embodiment or example. Moreover, the specific features, structures, materials, or characteristics described can be appropriately combined in one or more embodiments or examples. In addition, those skilled in the art can combine and merge different embodiments or examples and the features of the different embodiments or examples described in this disclosure, in the condition that no contradiction exists.

The above descriptions are only examples of the present disclosure and do not mean to limit the present disclosure. For those skilled in the art, this disclosure may have various modifications and alternations. Any modifications, equivalent alternatives, improvements, etc., made within the spirit and principle of this disclosure fall within the scope of the claims.

What is claimed is:

1. A method for managing battery data, comprising:
acquiring cell data and battery data, which describe statuses of a cell and a battery pack, respectively;
calculating an estimated battery status, which indicates a status of the cell and the battery pack after an estimation time period, based on the cell data and the battery data; and
sending an alarm message to a user if the estimated battery status meets a battery failure condition.

2. The method according to claim 1, wherein the battery includes an onboard battery, and acquiring the cell data and the battery data comprises:
acquiring the cell data, the battery data, and vehicle data, wherein the vehicle data includes at least one of vehicle speed and vehicle location, and
calculating the estimated battery status based on the cell data and the battery data comprises:
calculating the estimated battery status based on the cell data, the battery data, and the vehicle data.

3. The method according to claim 1, wherein the cell data includes at least one of cell temperature, cell voltage, and cell charging/discharging current, and
the battery data includes at least one of the following: battery-pack voltage, battery-pack temperature, and battery-pack charging/discharging current.

4. The method according to claim 1, wherein the cell data and/or the battery data includes data recorded in at least one format of Excel, CSV/TXT, Measurement Data Format (MDF) and Controller Area Network (MAY), or real-time data sent by an onboard BMS wireless terminal.

5. The method according to claim 1, further comprising preprocessing the cell data and/or the battery data after the cell data and the battery data are acquired, wherein
the preprocessing comprises at least one of the following: removing invalid data, denoising, complementing missing data, and transcoding.

6. The method according to claim 1, wherein calculating the estimated battery status based on the cell data and the battery data comprises:
calculating the estimated battery status with a status estimating model based on the cell data and the battery data, wherein the status estimating model includes a neural network model for estimating a state of charge and the battery status.

7. The method according to claim 6, wherein the status estimating model is obtained by:
creating a battery-system simulation environment, wherein the battery-system simulation environment includes a numerical solver and/or a physical battery model;
acquiring sample battery data, wherein the sample battery data is labeled with a battery failure status; and
training a pre-built status estimating model based on the sample battery data.

8. The method according to claim 1, wherein the battery failure condition includes at least one of an over-voltage failure condition, an under-voltage failure condition, an over-temperature failure condition, an over-current failure condition, a low charge condition, and a low power condition.

9. The method according to claim 1, wherein sending the alarm message to the user comprises:
sending a report corresponding to the estimated battery status to the user via email; and/or
displaying data corresponding to the estimated battery status to the user via a visual interface.

10. A device for managing battery data, comprising:
a data acquiring module configured to acquire cell data and battery data, wherein the data acquiring module describes the statuses of a cell and a battery pack, respectively;
a battery status estimating module configured to calculate an estimated battery status, wherein the battery status estimating module indicates a status of the cell and the battery pack after an estimation time period, based on the cell data and the battery data; and
an alarm message sending module configured to send an alarm message to a user if the estimated battery status meets a battery failure condition.
